(19) United States
(12) Patent Application Publication
(10) Pub. No.: US 2010/0259332 A1
(43) Pub. Date: Oct. 14, 2010

(54) COMPENSATION CIRCUIT FOR VOLTAGE CONTROLLED OSCILLATOR

(76) Inventor: Seeteck TAN, Singapore (SG)

Correspondence Address: O2MICRO INC;C/O MURABITO, HAO & BARNES LLP, TWO NORTH MARKET STREET, THIRD FLOOR, SAN JOSE, CA, 95113, US

(21) Appl. No.: 12/421,884

(22) Filed: Apr. 10, 2009

(51) Int. Cl. H03L 5/00

(52) U.S. Cl. 331/17

(57) ABSTRACT

A circuit can be used to a control the voltage of a voltage controlled oscillator (VCO) can include a first comparator, a second comparator, an accumulator, and an output device. The first comparator outputs a first pulse signal when the control voltage is higher than a high threshold voltage. The second comparator outputs a second pulse signal when the control voltage is lower than a low threshold voltage. The accumulator increases the value of a switch control signal if the first pulse signal is received or decreases the value of the switch control signal if the second pulse signal is received. The output device generates a compensation voltage to compensate the control voltage of the VCO depending on the value of the switch control signal.

### TECHNICAL FIELD

Embodiments according to the invention relate to a phase locked loop (PLL), and more particularly, to a voltage controlled oscillator (VCO) in a PLL circuit.

### BACKGROUND ART

A voltage controlled oscillator (VCO) is usually used in wireless communication devices to enable the devices to operate at an assigned frequency. A VCO can be tuned to output a predetermined frequency. Typically, a VCO is incorporated into a frequency synthesizer that can include a phase locked loop (PLL) configured to maintain a control voltage of the VCO at a value that tunes the VCO output frequency to the predetermined frequency.

Referring to PRIOR ART FIG. 1, a conventional LC (inductor-capacitor) VCO 100 circuit is illustrated. The VCO 100 includes three p-channel metal-oxide-semiconductor (PMOS) devices 102, 104 and 106, a varactor 120, an inductor group 124 and differential outputs 126 and 128. The PMOS 102 is coupled to a source voltage V_{DD} and biased by a bias voltage V_{BIAS} to provide current to the VCO 100. The PMOS 104 and PMOS 106 are coupled to the PMOS 102 and provide negative-resistance for the VCO 100 to oscillate.

The output frequency of the differential outputs 126 and 128 of the VCO 100 is related to the inductance of the inductor group 124, and the capacitance of the varactor 120 which can be varied by a control voltage V_{TUNE} provided by the PLL. Thus, by tuning the capacitance of the varactor 120, the output frequency of the differential outputs 126 and 128 of the VCO 100 can be tuned.

As power supply V_{DD} and operating temperature vary, the tuning characteristic of VCO 100 will change, and the output frequency of the VCO 100 will thus change. To control the output frequency of the VCO 100 at a predetermined level, the varactor 120 can be tuned by the control voltage V_{TUNE}. However, if the control voltage V_{TUNE} varies too much and is outside the desired operating range, which is around half of the source voltage V_{DD}, the operating characteristics of the PLL can be affected.

### SUMMARY

According to embodiments of the invention, a circuit can be used to compensate a control voltage for a voltage controlled oscillator (VCO). In one embodiment, the compensation circuit includes a first comparator, a second comparator, an accumulator, and an output device. The first comparator compares the control voltage to a high threshold voltage and outputs a first pulse signal when the control voltage is higher than the high threshold voltage. The second comparator compares the control voltage to a low threshold voltage and outputs a second pulse signal when the control voltage is lower than the low threshold voltage. The accumulator increases the value of a switch control signal if the first pulse signal is received or decreases the value of the switch control signal if the second pulse signal is received. The output device is controlled by the switch control signal to generate a compensation voltage to compensate the control voltage of the VCO depending on the value of the switch control signal.

### BRIEF DESCRIPTION OF THE DRAWINGS

Features and advantages of embodiments of the invention will become apparent as the following detailed description proceeds, and upon reference to the drawings, where like numerals depict like elements, and in which:

FIG. 1 is a diagram showing a prior art voltage controlled oscillator (VCO).

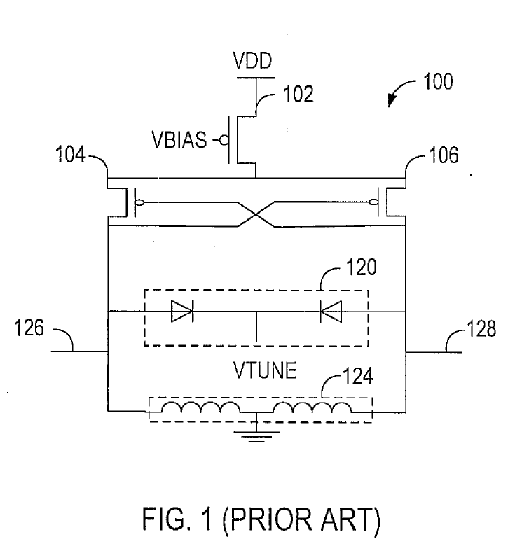

FIG. 2 is a diagram showing a phase locked loop (PLL) with a VCO compensation circuit, in accordance with one embodiment of the present invention.

FIG. 3 is a diagram showing a tuning characteristic of the VCO, in accordance with one embodiment of the present invention.

FIG. 4 is diagram showing a compensation circuit of the VCO, in accordance with one embodiment of the present invention.

FIG. 5 is a diagram showing a switch and resistor network, in accordance with one embodiment of the present invention.

FIG. 6 is a flowchart showing a method for generating a compensation voltage for the VCO, in accordance with one embodiment of the present invention.

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

In one embodiment, a compensation circuit is provided to compensate a control voltage V_{TUNE} of a VCO. Since the operating characteristics of the PLL can be affected if the control voltage V_{TUNE} varies outside of the desired operating range, the compensation circuit generates a compensation voltage V_{COMP}, based on the control voltage V_{TUNE}, to control the VCO. The compensation voltage V_{COMP} can also be used to control the output frequency of the VCO 100 without affecting the operating characteristics of the PLL. Also, the control voltage V_{TUNE} can be monitored and maintained in the desired operating range between a low threshold voltage and a high threshold voltage. As such, the PLL can operate stably.

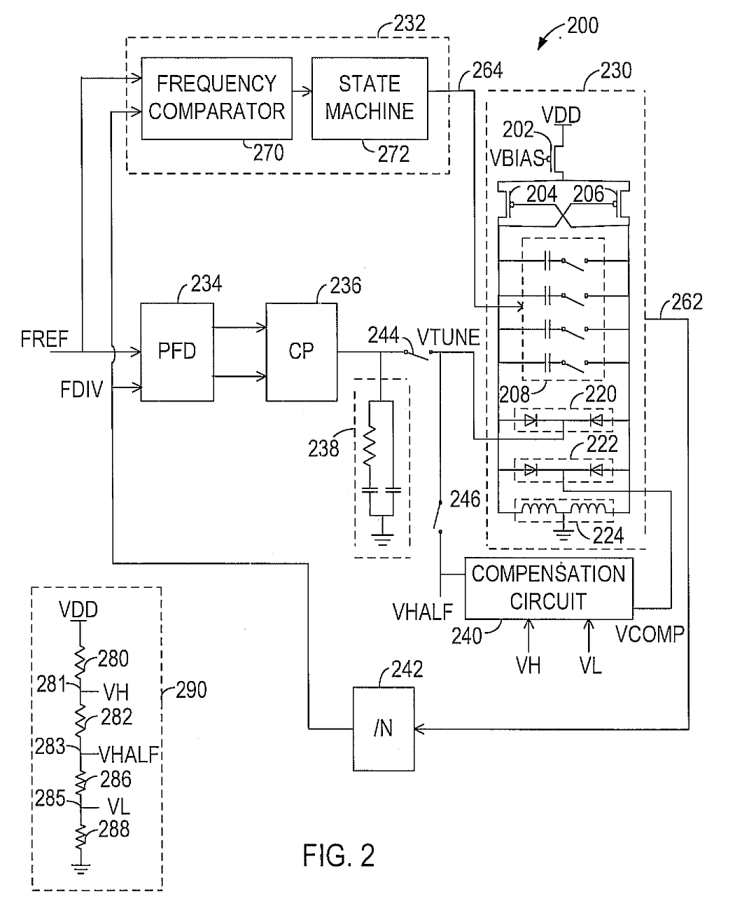

Referring to FIG. 2, a PLL 200 with a VCO compensation circuit 240 according to one embodiment of the present invention is illustrated. The PLL 200 includes a VCO 230, a frequency calibration loop 232, a phase frequency detector (PFD) 234, a charge pump (CP) 236, a loop filter 238, a frequency divider 242 and the compensation circuit 240. The PFD 234 compares the phases of two input signals: one signal is a reference frequency F_{REF} from an external source (not shown in FIG. 2), and the other signal is a divided frequency F_{DIV}, which is an output frequency 262 of the VCO 230 divided by the frequency divider 242. The CP 236 and the PFD 234 are used together to translate the phase difference between the reference frequency F_{REF} and the divided frequency F_{DIV} into a control voltage V_{TUNE}. The loop filter 238 then smoothes the control voltage V_{TUNE} and feeds it into the VCO 230.

In the embodiment of FIG. 2, the VCO 230 includes three PMOSes 202, 204 and 206, a switch capacitor network 208, two varactors 220 and 222, and an inductor group 224, and outputs an output frequency 262. The PMOS 202 is coupled to a source voltage V_{DD} and biased by a bias voltage V_{BIAS} to provide current to the VCO 230. The PMOS 204 and PMOS 206 are coupled to the PMOS 202 and provide negative-resistance for the VCO 230 to oscillate. The output frequency of the VCO 230 can be calculated using equation (1) as follows:

$${F}_{VCO} = \frac{1}{2 π \sqrt{{LC}_{total}}} \qquad ( 1 )$$

where F_{VCO} is the output frequency 262 of the VCO 230, L is the inductance of the inductor group 224, and Cₜₒₜₐₗ is the total capacitance of the VCO 230 and can be calculated using equation (2) as follows:

Cₜₒₜₐₗ=C_{switch}+C_{varactor1}+C_{varactor2}+C_{paracitic} (2)

where C_{switch} is the capacitance of the switch capacitor network 208, C_{varactor1} is the capacitance of the varactor 220, C_{varactor2} is the capacitance of the varactor 222, and C_{parasitic} is the parasitic capacitance due to the inductor group 224.

In the present embodiment, the switch network 208 includes several fixed-value capacitors that are coupled separately through switches in parallel to provide various capacitances by turning on some of the switches and turning off other switches. The capacitance of the varactor 220 in the VCO 230 can be varied by the control voltage V_{TUNE} provided by the PFD 234 and the CP 236. The capacitance of the varactor 222 in the VCO 230 can be varied by a compensation voltage V_{COMP} which is provided by the compensation circuit 240. Thus, by controlling the switch capacitor network 208 and the varactors 220 and 222, the output frequency of the VCO 230 can be tuned.

The frequency calibration loop 232 includes a frequency comparator 270 and a state machine 272 that provide a control signal 264 to control the switch capacitor network 208. The state machine 272 functions to select an appropriate frequency band of the VCO 230 based on an output from the frequency comparator 270. The frequency calibration loop 232 may be only activated once during startup of the PLL 200 and one control signal 264 is selected. During startup, the control signal 264 is set to an initial value and frequency compensation is performed. The value of the control signal 264 is increased until the desired frequency band is selected. In one embodiment, the control signal 264 is an n-bit digital binary signal and each bit corresponds to a switch in the switch capacitor network 208. By varying the bit numbers, some of the switches can be turned on while other switches can be turned off.

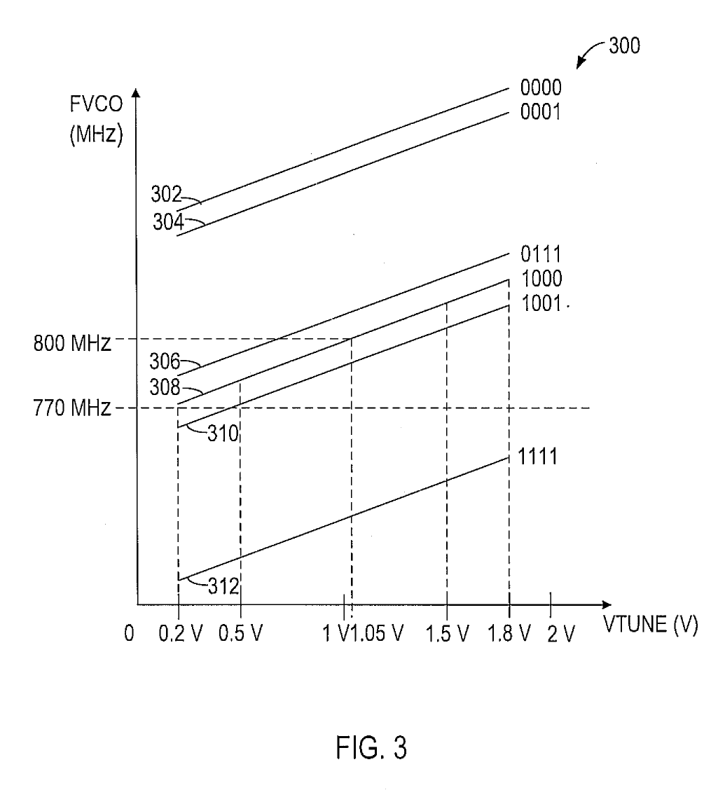

FIG. 3 is described herein with reference to the PLL 200 shown in FIG. 2. FIG. 3 illustrates an example tuning characteristic 300 of the VCO 230. The x-axis is the control voltage V_{TUNE} and the y-axis is the output frequency 262 of the VCO 230. The characteristics depicted in FIG. 3 are based on the following conditions: the source voltage VDD is 2.0 V, the temperature of the VCO 230 is 20° C. and not varied, the compensation voltage V_{COMP} is stable at 1.0 V, and the control signal 264 is a 4-bit digital binary signal. For easy explanation, operating characteristic curves 302, 304, 306, 308, 310 and 312 are assumed to be linear and to correspond to the control signal 264 as “0000”, “0001”, “0111”, “1000”, “1001” and “1111”. As such, each control signal 264 has a corresponding frequency band. To operate the PLL 200 shown in FIG. 2 at 800 MHz, or in other words, to maintain the output frequency 262 of the VCO 230 at 800 MHz, the control signal 264 of “1000” should be selected. In that case, the control voltage V_{TUNE} is very close to 1.05 V, which is around half of the source voltage V_{DD} and thus is in the desired operating range.

As previously noted herein, if the control voltage V_{TUNE} varies outside the desired range, the operating characteristics of the PLL 200 may be affected. Hence, under the conditions presented above, to maintain control of the current of the CP 236 and thus to avoid affecting the operating characteristics of the PLL 200, the control voltage V_{TUNE} should be in the range between a lower threshold and a higher threshold. Ideally, the operating range of the control voltage V_{TUNE} is limited to a narrow range that is about 1.0 V, which is half of the source voltage V_{DD}. By employing the compensation circuit 240 to monitor the control voltage V_{TUNE} and to ensure it falls between a high threshold voltage V_{H} and a low threshold voltage V_{L}, the control voltage V_{TUNE} can be controlled in the desired operating range. Also, a compensation voltage V_{COMP} is provided by the compensation circuit 240 to tune the output frequency of the VCO 240 to a predetermined level.

Thus, when the temperature of the PLL 200 is varying, instead of varying the control voltage V_{TUNE}, the compensation voltage V_{COMP}, which has the same function as the control voltage V_{TUNE}, can be varied. Since the operating range of the compensation voltage V_{COMP} is not as critical as the operating range of the control voltage V_{TUNE}, the output frequency 262 of the VCO 230 can be maintained at the predetermined level by tuning the compensation voltage V_{COMP}. Assuming the size of the varactor 220 and the varactor 222 in the VCO 230 are the same, the source voltage V_{DD} is 2.0 V. The desired operating voltage of the control voltage V_{TUNE} is thus about 1.0 V. For example, suppose the PLL 200 is operating at 20° C.; then, in order to output the predetermined 800 MHz output frequency 262, the control voltage V_{TUNE} should be 1.05 V. If the temperature then rises to 120° C., to keep the frequency of the output frequency 262 at 800 MHz, the control voltage V_{TUNE} should be 1.8 V, which is outside the desired range, potentially affecting operation of the PLL 200. By using the compensation voltage V_{COMP} and tuning it to 1.8 V, the frequency of the output clock 262 can be kept at 800 MHz while the control voltage V_{TUNE} can be maintained at 1.05 V. The compensation circuit 240 which provides the compensation voltage V_{COMP} is described in detail hereinafter.

Referring back to FIG. 2, during startup, a switch 244 between the charge pump 236 and the VCO 230 is turned off, while another switch 246 between the VCO 230 and a fixed voltage V_{HALF} is turned on. Usually, the value of the fixed voltage V_{HALF} is half of the value of the voltage source V_{DD}. As such, by turning off the switch 244 and turning on the switch 246, the control voltage V_{TUNE} is coupled to the voltage V_{HALF} and thus be calibrated.

According to one embodiment, a block 290 provides the fixed voltage VHALF, the high threshold voltage V_{H} and the low threshold voltage V_{L}. Resistors 280, 282, 284 and 286 are coupled in series between the source voltage V_{DD} and ground to provide the fixed voltage VHALF, the high threshold voltage V_{H} and the low threshold voltage V_{L} at the nodes 281, 283 and 285, respectively. Different numbers of resistors can be used to achieve different values for the fixed voltage VHALF, the high threshold voltage V_{H} and the low threshold voltage V_{L}.

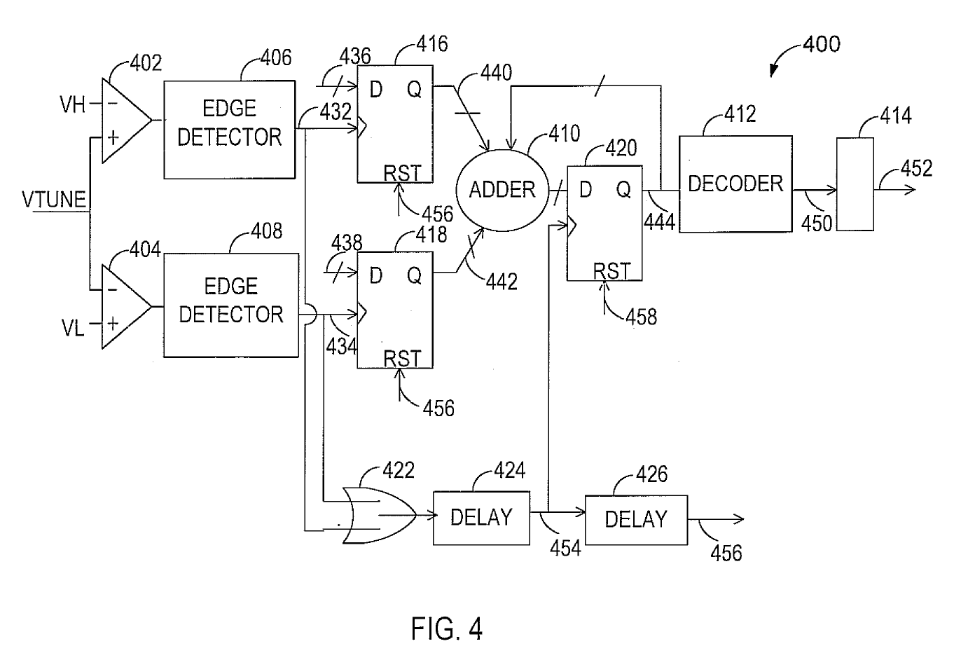

FIG. 4 illustrates an embodiment of a compensation circuit 400 such as the compensation circuit 240 shown in FIG. 2. In the example of FIG. 4, the compensation circuit 400 includes two comparators 402 and 404, two edge detectors 406 and 408, three flip-flops 416,418 and 420, an adder 410, a decoder 412, an output device, such as a switch and resistor network 414, a latch module 422, and two delay modules 424 and 426.

The comparator 402 compares the control voltage V_{TUNE} to the high threshold voltage V_{H}, and the comparator 404 compares V_{TUNE} to the low threshold voltage V_{L}, separately. If the control voltage V_{TUNE} is higher than the high threshold voltage V_{H}, the edge detector 406 will provide a pulse signal 432 to activate the flip-flop 416. When receiving the pulse signal 432, the flip-flop 416 outputs an adding value 440 equaling an input adding constant 436. Similarly, if the control voltage V_{TUNE} is lower than the low threshold voltage V_{L}, the edge detector 408 will provide a pulse signal 434 to activate the flip-flop 418. When receiving the pulse signal 434, the flip-flop 418 outputs a subtracting value 442 equaling an input subtracting constant 438. The adder 410 and the flip-flop 420 serves as an accumulator for increasing or decreasing an output value 444 from the last accumulator cycle by adding the adding value 440 or the subtracting value 442 to the output value 444 of the last accumulator cycle. In this specification, the “last accumulator cycle” refers to the last time that the accumulator was activated by the pulse signal 432 or 434 and outputted the output value 444. The values of the adding constant 436 and the subtracting constant 438 depend on the value of a step number as described below.

Then, the decoder 412 decodes the new output value 444 to a switch control signal 450 to control the switch and resistor network 414.

In one embodiment according to the present invention, the adding constant 436 is an n-bit digital binary number of which the lowest bit is “1” and other bits are “0”s. The subtracting constant 438 is an n-bit digital binary number of which all bits are “1”s. Correspondingly, the output value 444 is also an n-bit digital binary number. For example, assuming that “n” is three and the step number is “1”, then the adding constant 436 will be “001” and the subtracting constant 438 will be “111”; supposing the last cycle output value 444 is “010”, the new output value will be “011” if the adding constant 436 is added, or the new output value will be “001” if the subtracting constant 438 is added. Thus, by adding the adding constant 436 or the subtracting constant 438, the output value 444 will be increased or decreased by “1”. Accordingly, the switch control signal 450 will be varied.

The switch and resistor network 414 includes several switches and resistors (not shown in FIG. 4) to provide several voltage levels. The difference between every two adjacent voltage levels is defined as a step change. The compensation voltage V_{COMP} equals one of the voltage levels depending on the switch control signal 450. Thus, when the switch control signal 450 is varied, the compensation voltage V_{COMP} will also be varied. In one embodiment, when the switch control signal 450 increases or decreases a step number, the compensation voltage V_{COMP} increases or decreases a step change.

The latch module 422 is used for combining the pulse signals 432 and 434. In one embodiment, the latch module 422 is an OR gate. The delay module 424 is used for delaying the pulse signal 432 or 434 for a time period then feeding a delayed pulse signal 454 into the flip-flop 420 to activate it. The delay module 426 are used for delaying the delayed pulse signal 454 for a time period then providing a reset signal 456 to reset the flip-flops 416 and 418. In one embodiment, the delay time period can be adjusted according to different requirements. During startup, the flip-flop 420 can be initialized by an external reset signal 458.

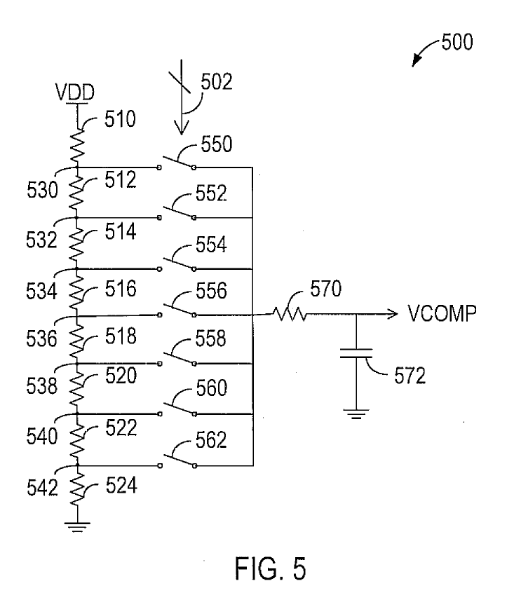

FIG. 5 illustrates an example switch and resistor network 500 such as the switch and resistor network 414 shown in FIG. 4. The switch and resistor network 500 includes resistors 510, 512, 514, 516, 518, 520, 522 and 524 coupled in series between a voltage source V_{DD} and ground, switches 550, 552, 554, 556, 558, 560 and 562, a resistor 570 and a capacitor 572. The switches 550, 552, 554, 556, 558, 560 and 562 are coupled to the nodes 530, 532, 534, 536, 538, 540 and 542 between each pair of the resistors 510, 512, 514, 516, 518, 520, 522 and 524. Although a certain number of resistors and switches are shown in FIG. 5, the present invention is not limited to the number shown and described. In one embodiment, assuming the source voltage V_{DD} is 2.0 V and all resistances of the resistors are equal, then the voltage of the nodes 530, 532, 534, 536, 538, 540 and 542 are 1.75 V, 1.5 V, 1.25 V, 1.0 V, 0.75 V, 0.5 V, and 0.25 V, respectively. Thus, the step change of the compensation voltage V_{COMP} is 0.25 V. By turning on one of the switches and turning off other switches according to the switch control signal 502, the compensation voltage V_{COMP} can be tuned.

In one embodiment, the switch control signal 502 is an m-bit digital binary signal and the bit number “m” corresponds to the switch number. In other words, each bit of the switch control signal 502 corresponds to one switch. Taking the switches 550, 552, 554, 556, 558, 560 and 562 for example, switch control signal 502 can be a 7-bit digital binary signal such as “0001000”. In this case, the switch 556 is turned on and other switches are turned off, and the compensation voltage V_{COMP} is the voltage of the node 536.

The resistor 570 and the capacitor 572 form a low pass filter and set a time constant for the compensation voltage V_{COMP}. The time constant controls the slew rate of the compensation voltage V_{COMP} in order to not perturb the output frequency 262 of the VCO 230 shown in FIG. 2. The resistor 570 and the capacitor 572 can be selected according to equation (3):

$${BW}_{COMP} = \frac{1}{2 π {R}_{COMP} {C}_{COMP}} \qquad ( 3 )$$

where BW_{COMP} is the bandwidth of the compensation voltage V_{COMP}, R_{COMP} is the resistance of the resistor 570, and C_{COMP} is the capacitance of the capacitor 572.

For example, if the loop bandwidth of the PLL 200 in FIG. 2 is 100 KHz, the BW_{COMP} can be selected to be ten times lower, so as to not the perturb the output frequency 262 of the VCO 230 in FIG. 2. In one embodiment, the network 500 is implemented without resistor 570 when the equivalent resistance of switches 550, 552, 554, 556, 558, 560 and 562 is large enough.

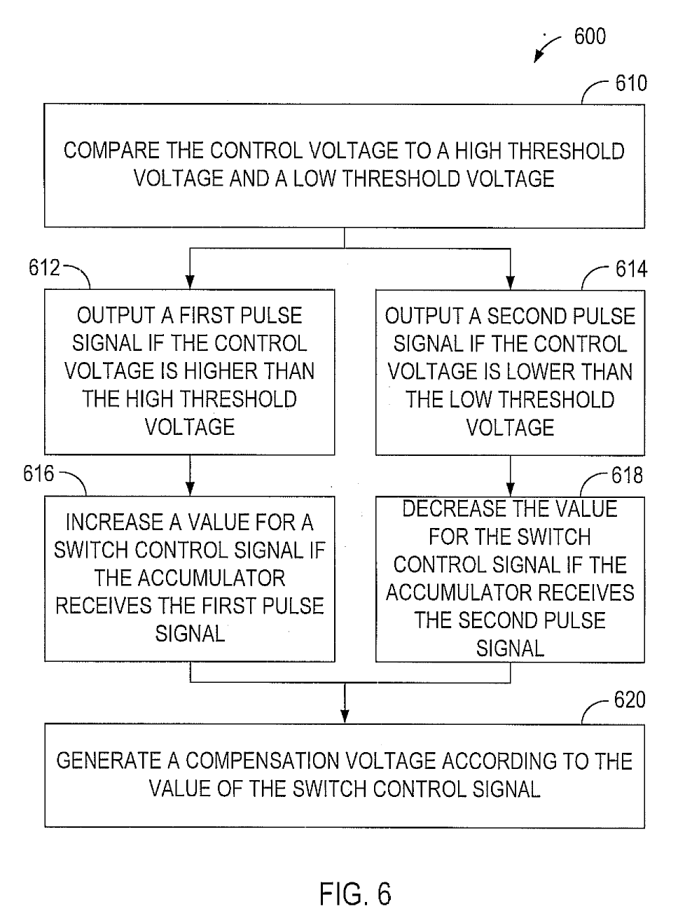

FIG. 6 illustrates a method 600 for compensating a control voltage V_{TUNE} of the voltage controlled oscillator (VCO) according to one embodiment of the present invention. FIG. 6 is described in combination with FIG. 4. As shown in FIG. 4, the compensation circuit 400 includes two comparators 402 and 404, two edge detectors 406 and 408, three flip-flops 416, 418 and 420, an adder 410, a decoder 412, a switch and resistor network 414, a latch module 422, and two delay modules 424 and 426.

At the beginning, the compensation circuit 400 in FIG. 4 is initialized. During the startup, an accumulator including the adder 410 and the flip-flop 420 is initialized by a reset signal 458 in FIG. 4.

At step 610, the comparators 402 and 404 compare the control voltage V_{TUNE} to a high threshold voltage V_{H} and a low threshold voltage V_{L}, separately.

At step 612, the edge detector 406 outputs a pulse signal 432 if the control voltage V_{TUNE} is higher than the high threshold voltage V_{H}, and the step 616 is then executed.

At step 614, the edge detector 408 outputs a pulse signal 434 if the control voltage V_{TUNE} is lower than the low threshold voltage V_{L}, and the step 618 is then executed.

At step 616, the accumulator, which includes the adder 410 and the flip-flop 420, adds a step number to an output value 444 of the last accumulator cycle according to the pulse signal 432. The adder 410 adds the adding value 440 and the output value 444 of the last cycle together to add the step number to the output value. As such, a switch control signal 450 corresponding to the output value 444 will be increased.

At step 618, the accumulator, which includes the adder 410 and the flip-flop 420, subtracts a step number from an output value 444 of the last accumulator cycle according to the pulse signal 434. The adder 410 adds the subtracting value 442 and the output value 444 of last cycle together to subtract the step number from the output value. As such, a switch control signal 450 corresponding to the output value 444 will be decreased.

At step 620, the switch and resistor network 414 outputs a compensation voltage V_{COMP} according to the control signal 450. The switch and resistor network 414 includes several switches and resistors (not shown in FIG. 4) for providing several voltage levels by turning on some of the switches and turning off other switches according to the switch control signal 450. The compensation voltage V_{COMP} equals one of the voltage levels according to the switch control signal 450. Thus, when the switch control signal 450 is increased by adding the step number or decreased by subtracting the step number, the compensation voltage V_{COMP} will also be increased or decreased, respectively. As such, the control voltage V_{TUNE} can be back to the desired operating range.

While the foregoing description and drawings represent the embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A circuit for compensating a control voltage of a voltage controlled oscillator (VCO), comprising:
a first comparator for comparing said control voltage to a high threshold voltage and for outputting a first pulse signal when said control voltage is higher than said high threshold voltage;
a second comparator for comparing said control voltage to a low threshold voltage and for outputting a second pulse signal when said control voltage is lower than said low threshold voltage;
an accumulator coupled to said first comparator and said second comparator for generating a switch control signal having a value, said generating comprising increasing said value by an adding value if said first pulse signal is received and decreasing said value by a subtracting value if said second pulse signal is received; and
an output device controlled by said switch control signal for generating a compensation voltage that compensates said control voltage of said VCO.

2. The circuit of claim 1, wherein said accumulator comprises an adder for adding said adding value to said value of said switch control signal if said first pulse signal is received and for adding said subtracting value to said switch control signal if said second pulse signal is received.

3. The circuit of claim 2, wherein said accumulator further comprises a first flip-flop coupled to said adder for providing said value of said switch control signal to said adder.

4. The circuit of claim 3, further comprising a first delay module for generating a delayed pulse signal to activate said first flip-flop by delaying said first pulse signal and said second pulse signal a first predetermined time period.

5. The circuit of claim 2, further comprising:
a second flip-flop for outputting, to said adder, said adding value equaling an adding constant if said second flip-flop is activated by said first pulse signal; and
a third flip-flop for outputting, to said adder, said subtracting value equaling an subtracting constant if said third flip-flop is activated by said second pulse signal.

6. The circuit of claim 5, further comprising a first delay module for generating a delayed pulse signal to activate said first flip-flop by delaying said first pulse signal and said second pulse signal for a first predetermined time period.

7. The circuit of claim 6, further comprising a second delay module for generating a reset signal to reset said second flip-flop and said third flip-flop by delaying said delayed pulse signal for a second predetermined time period.

8. The circuit of claim 1, wherein said output device comprises:
a plurality of resistors coupled between a source voltage and ground for dividing said source voltage into a plurality of voltages; and
a plurality of switches coupled to said plurality of resistors for outputting said compensation voltage equaling one of said voltages by turning on a corresponding one of said switches.

9. The circuit of claim 8, wherein said output device further comprises:
a resistor coupled to said plurality of switches; and
a capacitor coupled to said resistor and ground for setting a time constant for said compensation voltage so as to control a slew rate of said compensation voltage.

10. A phase locked loop (PLL) for providing a predetermined output frequency, comprising:
a voltage controlled oscillator (VCO) for generating an output frequency;
a phase frequency detector (PFD) coupled to said VCO;
a charge pump (CP) coupled to said PDF for providing a control voltage for said VCO so as to tune said output frequency to said predetermined level by comparing said output frequency with an external reference frequency; and
a compensation circuit coupled to said CP and said VCO for monitoring said control voltage in a desired operating range and for providing a compensation voltage that is varied based on said control voltage to control said VCO.

11. The PLL of claim 10, further comprising a loop filter coupled to said CP for smoothing said control voltage.

12. The PLL of claim 10, further comprising a frequency calibration loop for calibrating said VCO at startup and tuning said output frequency in a specific band by providing a control signal to said VCO.

13. The PLL of claim 12, wherein said control signal is a digital number.

14. The PLL of claim 10, wherein said compensation circuit comprises:
a first comparator for comparing said control voltage to a high threshold voltage and for outputting a first pulse signal when said control voltage is higher than said high threshold voltage;
a second comparator for comparing said control voltage to a low threshold voltage and for outputting a second pulse signal when said control voltage is lower than said low threshold voltage;
an accumulator coupled to said first comparator and said second comparator for generating a switch control signal having a value, said generating comprising increasing said value by an adding value if said first pulse signal is received and decreasing said value by a subtracting value if said second pulse signal is received; and
an output device controlled by said switch control signal for generating said compensation voltage that compensates said control voltage of said VCO.

15. The PLL of claim 14, wherein said accumulator comprises an adder for adding said adding value to said value of said switch control signal if said first pulse signal is received and for adding said subtracting value to said switch control signal if said second pulse signal is received.

16. The PLL of claim 15, wherein said accumulator further comprises a first flip-flop coupled to said adder for providing said value of said switch control signal to said adder.

17. The PLL of claim 14, further comprising:
a second flip-flop for outputting, to said adder, said adding value equaling an adding constant if activated by said first pulse signal; and
a third flip-flop for outputting, to said adder, said subtracting value equaling an subtracting constant if activated by said second pulse signal.

18. The PLL of claim 14, wherein said output device comprises:
a plurality of resistors coupled between a source voltage and ground for dividing said source voltage into a plurality of voltages; and
a plurality of switches coupled to said plurality of resistors for outputting said compensation voltage equaling one of said voltages by turning on a corresponding one of said switches.

19. A method for compensating a control voltage for a voltage controlled oscillator, said method comprising:
comparing said control voltage with a high threshold voltage and a low threshold voltage;
outputting a first pulse signal if said control voltage is higher than said high threshold voltage;
outputting a second pulse signal if said control voltage is lower than said low threshold voltage;
increasing a value for a switch control signal by an adding value using an accumulator if said accumulator receives said first pulse signal;
decreasing said value of said switch control signal by subtracting a subtracting value if said accumulator receives said second pulse signal; and
generating a compensation voltage according to said value of said switch control signal by an output device.

20. The method as claimed in claim 19, further comprising:
initializing said switch control signal of said accumulator by an external reset signal during startup of said accumulator.
